(19) United States
(12) Patent Application Publication
(10) Pub. No.: US 2006/0138657 A1
(43) Pub. Date: Jun. 29, 2006

(54) Semiconductor device and fabrication method thereof

(76) Inventor: Yoshimasa Kushima, Yamana-shi (JP)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/315,348

(22) Filed: Dec. 23, 2005

(30) Foreign Application Priority Data
Dec. 28, 2004 (JP) 2004-378564

(51) Int. Cl. H01L 23/48

(52) U.S. Cl. 257/737

(57) ABSTRACT

A semiconductor device has rewiring that is electrically connected to circuit elements on a semiconductor substrate, and a plurality of posts electrically connected to the rewiring. The semiconductor device also has a sealing layer that seals the rewiring and the posts. A column-like identification protrusion whose cross-sectional shape is the shape of an identification mark for identifying the direction of the semiconductor device is provided. The identification protrusion is formed on the rewiring at the same time the posts are created. The end face of the identification protrusion is exposed at the upper face of the sealing layer and used as the identification mark of the semiconductor device.

### BACKGROUND OF THE INVENTION

1. Field of the Invention

The present invention relates to a wafer-level chip size package-type semiconductor device that is formed by dividing a semiconductor wafer on which a plurality of circuit elements is formed into individual pieces, and to a method of fabricating the wafer-level chip size package-type semiconductor device.

2. Description of the Related Art

In recent years, in accordance with the miniaturization and increase in the functions of electronic devices, the mounting density of parts on a wiring substrate has risen. As a result of this increased density, the miniaturization of semiconductor devices, reductions in the interval between pins and increases in the number of pins have accelerated. In order to meet the needs of downsizing of semiconductor devices, wafer-level chip size package-type semiconductor devices that are substantially the same size as the size achieved when semiconductor wafers are divided into individual pieces have come into the mainstream.

In the the conventional semiconductor devices of this wafer-level chip size package-type, rewiring that is electrically connected to circuit elements formed on the upper face of a semiconductor substrate and posts that are electrically connected to the rewiring are sealed by means of a sealing layer, and then a protruding electrode is provided on an upper end face of each post. Pin marks are made on the lower face of the semiconductor devices and the semiconductor devices are divided into individual pieces from the semiconductor wafer in accordance with the pin marks. These semiconductor devices are stored temporarily in a tape & reel packaging or tray after being oriented in the same direction. When the stored semiconductor devices are mounted on a wiring substrate alignment between the protruding electrodes of the semiconductor devices and the wiring terminals of the wiring substrate is executed by using the pin marks. These conventional semiconductor devices are disclosed in, for example, Japanese Patent Application Kokai (Laid Open) No. 2003-60120 (mainly paragraph 0037 of page 5 to paragraph 0041 of page 6, and FIG. 4).

In the case of the conventional technology above, the semiconductor devices having the pin marks in the lower face thereof are stored in the tape & reel packaging or the tray, and the lower faces of the semiconductor devices are directed downward when the semiconductor devices are placed in the tray. Thus, it is difficult for workers or inspection persons to visually confirm the direction of the semiconductor devices stored in the package or tray.

The protruding electrodes of the semiconductor device and the wiring terminals of the wiring substrate are aligned by using the pin marks that are provided (stamped) on the lower face of the semiconductor device, but there could be some variations in the pin-mark stamping accuracy and/or the cutting accuracy when the semiconductor wafer is divided into individual pieces. Thus, it is sometimes difficult to confirm the positions of the protruding electrodes correctly and misalignment is produced between the protruding electrode and wiring terminal.

### SUMMARY OF THE INVENTION

An object of the present invention is to enable correct alignment of protruding electrodes and wiring terminals.

Another object of the present invention is to enable easy confirmation of the directions of semiconductor devices that are stored with the lower face facing downward.

According to a first aspect of the present invention, there is provided a semiconductor device that includes a semiconductor substrate, and one or more circuit elements that are formed on a circuit formation face of the semiconductor substrate. The semiconductor device also includes rewiring that is electrically connected to the circuit elements, and a plurality of posts that are electrically connected to the rewiring. The semiconductor device also includes a sealing layer that seals the rewiring and the posts. A column-like identification protrusion is formed on the rewiring and arranged in the vicinity of one of the posts. The identification protrusion is also sealed by (embedded in) the sealing layer, but an upper end face of the identification protrusion is exposed at the upper face of the sealing layer and is used as a mark for identifying the direction of the semiconductor device.

An identification protrusion can be formed in the upper face of the semiconductor substrate in a wafer state. Thus, the positional accuracy of the protruding electrodes that are formed on the end faces of the posts formed on the semiconductor wafer can be improved. The positions of the protruding electrode can be accurately identified by using the shape of the identification protrusion end face (i.e., identification mark) exposed at the upper face of the sealing layer. The alignment of the wiring terminals when the semiconductor device is mounted can be correctly performed. The identification mark can be provided in the upper face of the semiconductor device. Thus, the direction of the semiconductor device stored with the lower face thereof facing downward can be easily confirmed.

These and other objects, aspects and advantages of the present invention will become apparent to those skilled in the art from the following detailed description and appended claims when read and understood in conjunction with the accompanying drawings.

### BRIEF DESCRIPTION OF THE DRAWINGS

FIG. 1 is a plan view of a semiconductor device according to a first embodiment of the present invention;

FIG. 2 is a cross-sectional view taken along the line II-II in FIG. 1;

FIGS. 3A to 3G is a series of diagrams of processes to fabricate a semiconductor wafer of the first embodiment;

FIG. 4 is a plan view of the semiconductor wafer of the first embodiment;

FIGS. 5A to 5D is a series of diagrams of processes to fabricate a semiconductor device from the semiconductor wafer of FIG. 4;

FIGS. 6A and 6B is diagrams of the process of mounting the semiconductor device on a wiring substrate;

FIG. 7 is a plan view of an example where the identification mark of the first embodiment is formed on a small semiconductor device;

FIG. 8 illustrates an enlarged view of a portion B of FIG. 7;

FIG. 9 is an enlarged view of a modification to the first embodiment; and

FIG. 10 is an enlarged view of a corner of the semiconductor device of a second embodiment.

### DETAILED DESCRIPTION OF THE INVENTION

Embodiments of the semiconductor device and method of fabricating same of the present invention will be described hereinbelow with reference to the drawings.

### First Embodiment

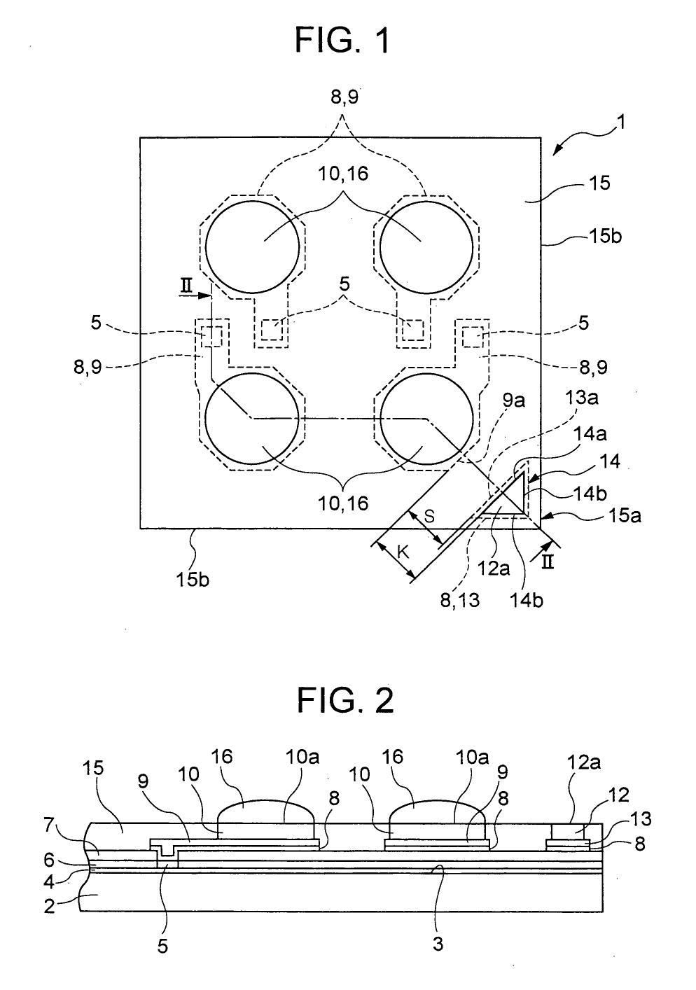

Referring to FIGS. 1 and 2, the semiconductor device 1, namely a wafer-level chip size package-type semiconductor device, will be described.

The semiconductor device 1 has a substrate 2 made from silicon. On the upper face of the substrate 2, there are a plurality of circuit elements (not shown) to which a plurality of semiconductor elements are connected by wiring. The upper face of the semiconductor substrate 2 where the circuit elements are formed is called the ‘circuit formation face 3’.

An insulating layer 4 made from silicon dioxide or the like is formed on the circuit formation face 3 of the semiconductor substrate 2. A contact hole (not shown) is formed in the top of each of the circuit elements formed on the semiconductor substrate 2. A conductive layer (not shown) is provided inside the contact hole.

A plurality of electrode pads 5 are provided on the insulating layer 4. The electrode pads 5 are formed from silicon-containing aluminum or the like. Each electrode pad 5 is provided for each circuit element. Each electrode pad 5 is electrically connected to the associated circuit element via the conductive layer that is formed in the contact hole.

A passivation film 6 is formed from silicon nitride or the like. The passivation film 6 is a protective film that covers the top of the insulating layer 4 and the perimeter of each electrode pad 5.

An interlayer isolation film 7 is formed from a polyimide or the like. The interlayer isolation film 7 is provided on the passivation film 6 to alleviate stress acting on the semiconductor substrate 2.

A metal thin-film layer 8 is formed on the interlayer isolation film 7 and electrode pads 5.

It should be noted that the metal thin-film layer 8 may be a single layer or a composite layer. The metal thin-film layer 8 is preferably constituted by a composite layer having an upper layer and lower layer. In this case, the lower layer may exhibit strong adhesion to the electrode pads 5 and may be made from any material as long as the material prevents the dispersion of the substance constituting the upper layer toward the semiconductor substrate 2. Titanium, for example, is used. The upper layer may be made from any material as long as the material exhibits strong adhesion to the metal wiring layer formed on the top of the upper layer. Copper, for example, is used. The metal wiring layer is formed by subjecting the top of the upper layer to plating or the like.

Rewiring 9 is a wiring pattern that is formed by etching the metal wiring layer formed on the metal thin layer 8. The rewiring 9 electrically connects the posts 10 to the electrode pads 5. The posts 10 are formed using the same material as that of the rewiring 9 and are located in predetermined positions on the rewiring 9.

The posts 10 of this embodiment are column-like members of a substantially circular cross-sectional shape and are formed on the rewiring 9 as shown in FIG. 2. The posts 10 are formed substantially as a polygon when viewed from the top as shown in FIG. 1.

An identification protrusion 12 is arranged near one of the posts 10 and is a column-like member with a uniform cross-sectional shape. The identification protrusion 12 is formed from the same material as the post 10 and is provided on a particular part of the rewiring 9 (called ‘nonconductive rewiring 13’). The nonconductive rewiring 13 (or the identification protrusion 12) is not electrically connected to any circuit elements. The shape of an exposed upper end face 12a of the protrusion 12 functions as an identification mark 14.

A sealing layer 15 is formed by a sealing resin such as epoxy resin to cover the whole of the side of the circuit formation face 3 of the semiconductor substrate 2 except for the end faces 10a of the posts 10 and the end face 12a of the identification protrusion 12. In other words, the sealing layer 15 covers the interlayer isolation film 7, metal thin-film layer 8, rewiring 9 and nonconductive rewiring 13 and also covers the sides of the posts 10 and the side of the identification protrusion 12. The upper face of the sealing layer 15 is coplanar to the post end faces 10a and protrusion end face 12a. As a result, the protrusion end face 12a is exposed at the upper face of the sealing layer 15 and the identification mark 14 appears on the upper face of the sealing layer 15.

Protruding electrodes 16 are formed from solder or the like. The protruding electrodes 16 are joined to wiring terminals 43 of a wiring substrate 40. Each protruding electrode 16 is formed on the upper end face 10a of each post 10 and functions as an external terminal of the semiconductor device 1. The circuit elements formed on the semiconductor substrate 2 are connected to an external device via the electrode pads 5, the metal thin-film layer 8, the rewiring 9, the posts 10, and protruding electrodes 16.

The identification mark 14 is a mark for identifying the direction of the semiconductor device 1. The identification mark 14 is a triangle that is formed in one corner 15a of the upper face of the sealing layer 15 in this embodiment. That is, the identification mark 14 has a shape that is constituted by an oblique side, which is an adjoining side 14a spaced by a predetermined interval K shown in FIG. 1 from a rewiring side 9a of an octagon of the rewiring 9 to which the neighboring post 10 is connected, and by two sides 14b that extend in parallel to two sealing layer sides 15b that form the corner 15a of the sealing layer 15. This is a right-angled triangle formed by the oblique side 14a and the two orthogonal sides 14b when the semiconductor device 1 is square as shown in FIG. 1. In this embodiment, because the oblique side 14a is in parallel to the rewiring side 9a, the identification mark 14 is a right-angled isosceles triangle.

The location of the identification mark 14 can be anywhere as long as the rewiring 9 that conducts electricity to the circuit elements is not present directly below the identification mark 14. The identification mark 14 is preferably located in the corner 15a of the sealing layer 15 of the semiconductor device 1 because there is a relatively wide area for the identification mark 14.

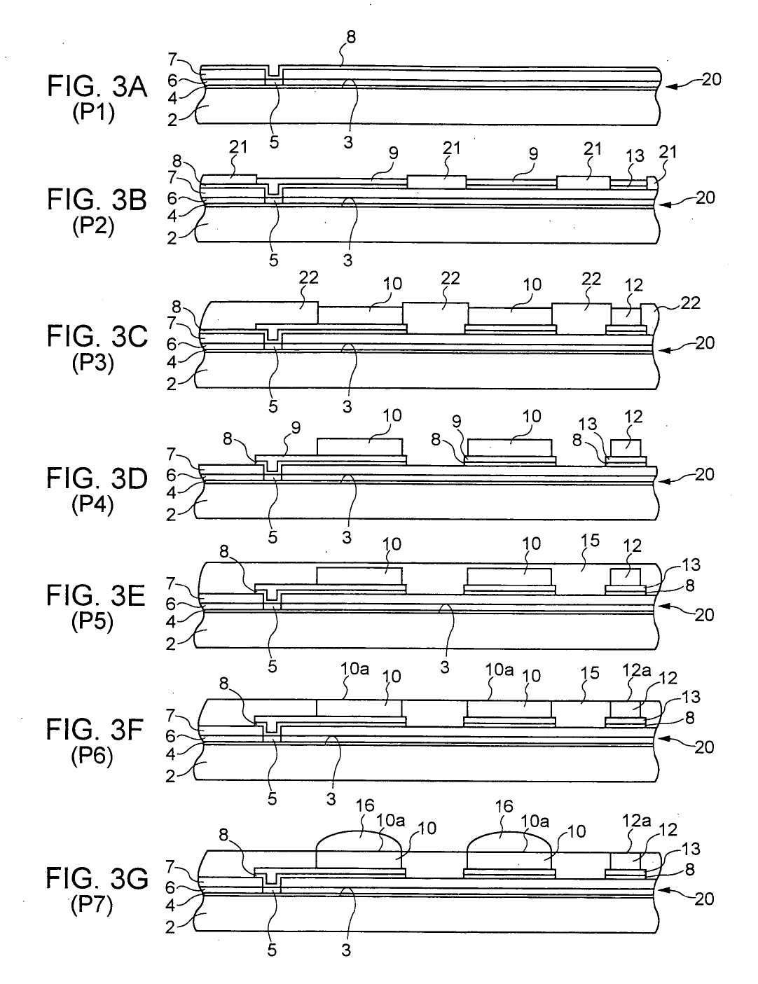

The method of fabricating the semiconductor device 1 of the first embodiment will be described hereinbelow by using FIG. 3A to FIG. 5D.

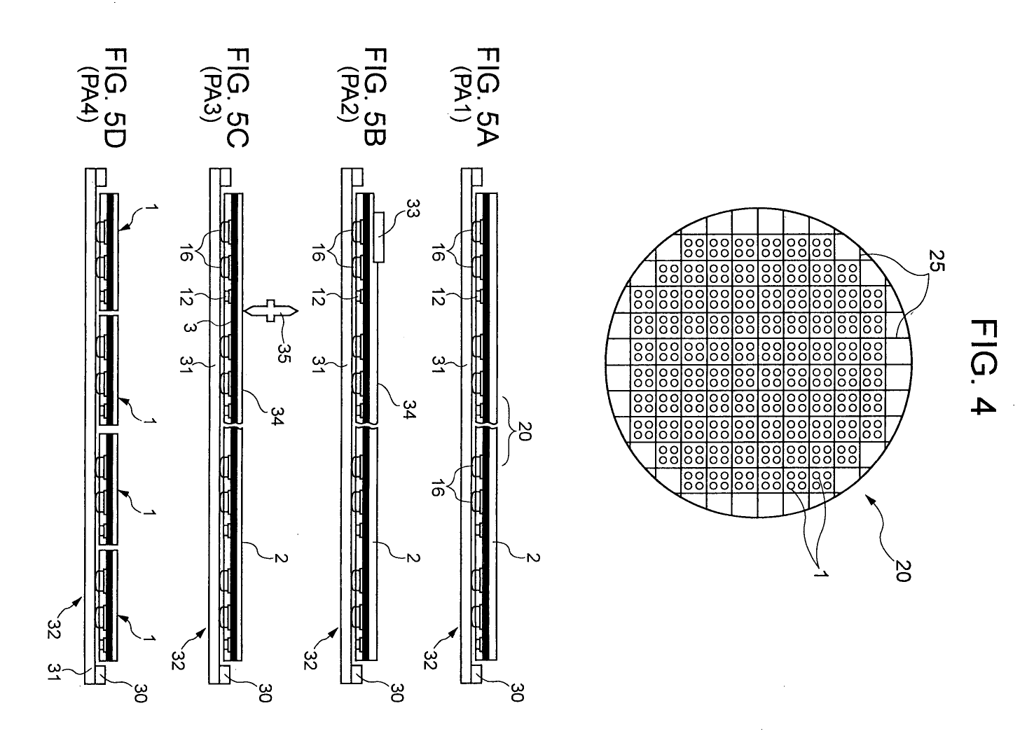

FIGS. 3A to 3G and FIGS. 5A to 5D show the fabrication process of the semiconductor device of the first embodiment. FIGS. 3A to 3G show the processes until the protruding electrodes 16 are formed. Seven processes are referred to as processes P1 to P7. FIGS. 5A to 5D show the processes until the semiconductor wafer 20 shown in FIG. 4 is divided into individual semiconductor devices. Four processes are referred to as processes PA1 and PA4.

FIGS. 3A to 3G show one of a plurality of semiconductor devices 1 that are formed on the semiconductor wafer 20. The seven processes P1 to P7 will be described in detail below.

P1 (FIG. 3A): A plurality of circuit elements (not shown) is formed on the circuit formation face 3 of a circular semiconductor substrate 2. The substrate 2 is prepared by slicing a column-shaped silicon rod. An insulating layer 4 is formed such that a contact hole (not shown) is situated above each circuit element. An electrically conductive layer (not shown) is provided in each contact hole.

Thereafter, a silicon-containing aluminum film is deposited on the insulating layer 4 by means of sputtering, and the electrode pads 5, which are electrically connected to predetermined parts of the circuit elements, are allowed to remain on the insulating layer 4 by etching the aluminum film in a predetermined shape.

Following the formation of the electrode pads 5, the passivation film (silicon nitride film) 6 is formed on the electrode pads 5 and insulating layer 4 by CVD (Chemical Vapor Deposition), and the passivation film 6 at the electrode pads 5 is removed by etching. Then, the interlayer isolation film (polyimide film) 7 is formed on the passivation film 6 and electrode pads 5, and the interlayer isolation film 7 at the electrode pads 5 is removed by etching.

Thereafter, the interlayer isolation film 7 is thermoset by means of heat treatment and the adhesion of the metal thin-film layer 8 is enhanced by reforming the upper face of the cured interlayer isolation film 7 by means of plasma etching in an inert gas (e.g., argon gas) atmosphere. Then, the metal thin-film layer 8 is formed on the interlayer isolation film 7 and electrode pads 5 by sputtering.

P2 (FIG. 3B): A resist 21 is formed on the metal thin-film layer 8 by means of lithography, and the resist except for the areas to be used as the rewiring 9 and nonconductive rewiring 13 is masked. The rewiring 9 and nonconductive rewiring 13 are formed by plating the exposed areas (portions) of the metal thin-film layer 8.

P3 (FIG. 3C): The resist 21 is removed by using a stripping agent such as acetone. A resist 22 is formed on the metal thin-film layer 8, rewiring 9 and nonconductive rewiring 13 once again by means of lithography, and the resist except for the areas for the posts 10 and identification protrusion 12 is masked. The posts 10 and identification protrusion 12 are formed on the exposed rewiring 9 and nonconductive rewiring 13 by plating using the same material as the rewiring 9.

P4 (FIG. 3D): The resist 22 is removed by means of stripping agent, the exposed metal thin-film layer 8 is removed by means of plasma etching in an oxygen gas atmosphere, and the surface layer of the exposed interlayer isolation film 7 is removed by wet etching. As a result, leakage of current flowing through the rewiring 9 to the other rewiring 9 and nonconductive rewiring 13 via the surface layer of the interlayer isolation film 7 can be prevented and the conduction between the nonconductive rewiring 13 and circuit elements can be reliably broken.

P5 (FIG. 3E): The whole of the semiconductor wafer 20 is inserted in a sealing die (not shown). Sealing resin is injected into the sealing die to seal the side of the circuit formation face 3 of the semiconductor substrate 2. The sealing resin is then cured to form the sealing layer 15.

P6 (FIG. 3F): The surface layer of the sealing layer 15 is polished and the end faces 10a of the posts 10 and the end face 12a of the identification protrusion 12 are exposed at the polished upper face. As a result, the upper face of the sealing layer 15 becomes coplanar to the post end faces 10a and protrusion end face 12a. Also, the interlayer isolation film 7, metal thin-film layer 8, rewiring 9, nonconductive rewiring 13, sides of the posts 10, and the side of the identification protrusion 12 are sealed by the sealing layer 15.

P7 (FIG. 3G): Protruding electrodes 16 with a substantially hemispherical shape are formed on the end faces 10a of the posts 10 by means of screen printing or the like.

As a result of these processes, the semiconductor wafer 20 having a plurality of semiconductor devices 1 formed thereon is formed as shown in FIG. 4. These semiconductor devices 1 are spaced from each other by a plurality of scribe areas 25 provided vertically and horizontally on the wafer 20. The wafer 20 will be divided into individual pieces based on the scribe areas 25.

The process of fabricating the semiconductor devices 1 by dividing the semiconductor wafer 20 into individual pieces 1 will now be described by using FIGS. 5A to 5D in accordance with the processes PA1 to PA5.

In FIGS. 5A to 5D, symbols have only been assigned to the parts of the semiconductor wafer 20 that are essential to the illustration but this semiconductor wafer is the semiconductor wafer 20 and has the whole constitution described above.

PA1 (FIG. 5A): A wafer holding tool 32 that has a ring-shaped wafer ring 30 and a dicing sheet 31 of UV tape or the like is prepared. The dicing sheet 31 possesses the characteristic that the bonding force drops upon UV irradiation. The protruding electrodes 16 of the inverted semiconductor wafer 20 are stuck to the dicing sheet 31 and the semiconductor wafer 20 is fixed to the wafer holding tool 32.

PA2 (FIG. 5B): The wafer holding tool 32 to which the semiconductor wafer 20 is fixed is installed in a grinding device (not shown). The grinding device has a whetstone 33 such as a diamond whetstone, and the lower face 34 of the semiconductor substrate 2 of the semiconductor wafer 20 is ground by means of the whetstone 33.

PA3 (FIG. 5C): Following the grinding of the lower face 34 of the semiconductor substrate 2, the wafer holding tool 32 to which the semiconductor wafer 20 is fixed is installed in a dicing apparatus (not shown). The dicing apparatus has a blade 35 and an infrared camera (not shown). The scribe areas (lines) 25 that exist in the upper face of the semiconductor wafer 20 are identified by identifying the pattern shape of the electrode pads 5 and rewiring 9 formed on the side of the circuit formation face 3 of the semiconductor substrate 2 from the lower face 34 of the semiconductor substrate 2 by means of the infrared camera. The blade 35 is positioned on the center line of the target scribe area 25.

PA4 (FIG. 5D): The blade 35 is moved along the center lines of the scribe areas 25, that is, along the scribe lines, thereby cutting the semiconductor wafer 20 vertically and horizontally to divide the semiconductor wafer 20 into individual pieces, that is, into the semiconductor devices 1.

The semiconductor wafer 20, which has been divided into individual pieces, is transferred to an expanding ring together with the dicing sheet 31. The dicing sheet 31 is irradiated with ultraviolet light to reduce the bonding strength, the gap between the respective semiconductor devices 1 is widened by expanding (pulling) the dicing sheet 31 in the radially outward direction of the semiconductor wafer 20, and the semiconductor devices 1 are removed from the dicing sheet 31 by means of an autohandler (not shown). The autohandler has an image identification device. The autohandler takes advantage of the increased gap. The semiconductor devices 1 are temporarily stored in a tape & reel packaging or a tray.

The autohandler uses the image identification device to identify (detect) the position of the identification mark 14 formed on the upper face of the sealing layer 15 of the semiconductor device 1 that is lifted by the autohandler and stores the semiconductor device 1 in the tape & reel packaging or the tray such that the semiconductor device 1 is arranged in the same direction as other semiconductor devices in the package or the tray while using the quadrant where the identification mark 14 is provided. In this case, the semiconductor devices 1 are stored in the tray with the protruding electrode 16 facing upward.

In this manner, the wafer-level chip size package-type semiconductor device 1 shown in FIGS. 1 and 2 is fabricated.

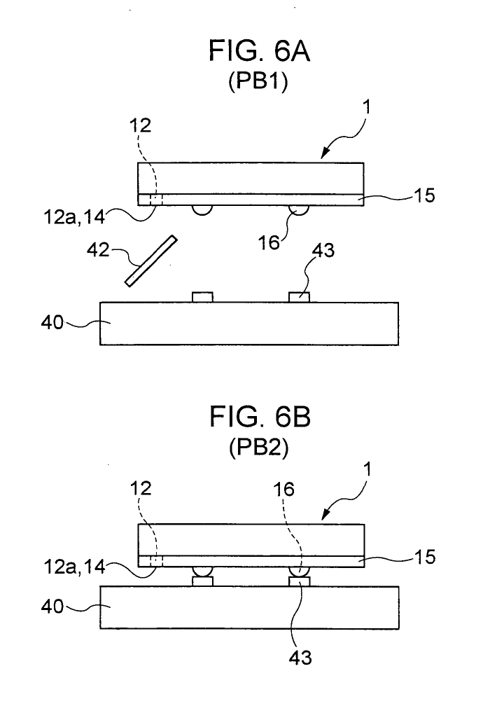

The process when mounting the semiconductor devices 1 temporarily stored in the tray or the like on the wiring substrate 40 will be described in accordance with the processes PB1 and PB2 in FIGS. 6A and 6B.

FIGS. 6A and 6B show the semiconductor device mounting process of the first embodiment.

PB1 (FIG. 6A): The semiconductor devices 1, which are temporarily stored in the tray, are taken from the tray by an automatic mounting device (not shown). The automatic mounting device has an image identification device. The semiconductor devices 1 are transported above the wiring substrate 40, with the protruding electrodes 16 being directed toward the wiring substrate 40.

Then, the image identification device of the automatic mounting device identifies the exposed end face 12a of the identification protrusion 12, that is, the shape of the identification mark 14 that is exposed at the upper face of the sealing layer 15 of the semiconductor device 1. The image of the identification mark 14 reflected by a half mirror 42 is detected by the image identification device. The automatic mounting device identifies the location of the specified protruding electrode 16 and the direction of the semiconductor device 1 by means of the detected identification mark 14.

PB2 (FIG. 6B): Thereafter, the specified protruding electrode 16 is located directly above the wiring terminal 43 that will join the specified protruding electrode 16, and the semiconductor device 1 directed in a predetermined direction is lowered toward the wiring substrate 40 to join the respective wiring terminals 43 and the corresponding protruding electrodes 16.

Mounting of the semiconductor device 1 on the wiring substrate 40 is performed as described above.

The semiconductor device 1 of this embodiment exposes the upper end face 12a of the identification protrusion 12 that is formed at the same time as the posts 10 are created on the upper face of the sealing layer 15 in a wafer state and uses the protrusion end face 12a as the identification mark 14. Therefore, irrespective of the cutting accuracy and so forth during division of the semiconductor wafer 20, the positional accuracy of the protruding electrodes 16 formed on the end faces 10a of the posts 10 and that of the identification mark 14 increases. By directly detecting the identification mark 14 with the half mirror 42, the position of the specified protruding electrode 16 can be accurately identified, and positional displacement when the semiconductor device 1 is mounted on the wiring substrate 40 can be prevented.

In this embodiment, because the cross-sectional shape of the identification protrusion arranged in the vicinity of a particular post is the shape of the identification mark and the protrusion end face is exposed at the upper face of the sealing layer, the identification protrusion can be formed on the upper face side of the semiconductor substrate in a wafer state. Thus, the positional accuracy between the identification protrusion and the protruding electrodes formed on the end faces of the posts formed on the semiconductor wafer can be improved, and the position of the protruding electrodes can be accurately identified by using the shape of the identification mark exposed at the upper face of the sealing layer. Also, alignment between the protrusion electrodes and the wiring terminals when the semiconductor device is mounted can be accurately performed. In addition, the identification mark can be provided on the upper face of the semiconductor device, so that the direction of the semiconductor device stored in the tray with the lower face of the semiconductor device facing downward can be easily identified by an inspection person.

Further, in the process of forming the posts on the rewiring during the fabrication process of the semiconductor wafer, the positional accuracy of the protruding electrodes formed on the post end faces and the identification mark can be further improved by simultaneously forming the posts and identification protrusion.

In addition, because the identification protrusion is formed to be nonconductive with the circuit elements, it is possible to prevent noise such as electrical noise from outside that is inputted to the identification protrusion from being transmitted to the circuit elements.

Also, by making the shape of the identification mark a triangle, a distinction from the shape of the protruding electrode (normally a circle) is straightforward, and identification of the direction of the semiconductor device that employs the image identification device can be performed easily. The direction of the semiconductor device can also be identified easily through visual observation by a worker or the like. Thus, the visual inspection becomes easier, simpler and more accurate.

By providing the identification mark in one corner of the sealing layer of the semiconductor device, it is possible to use a relatively wide area for the provision of the identification mark because the rewiring that conducts electricity to the circuit elements does not exist directly below the corner of the sealing layer. Thus, an identification mark with a relatively large area can be easily provided, and the detection of the identification mark by means of an image identification device or the like can be executed accurately.

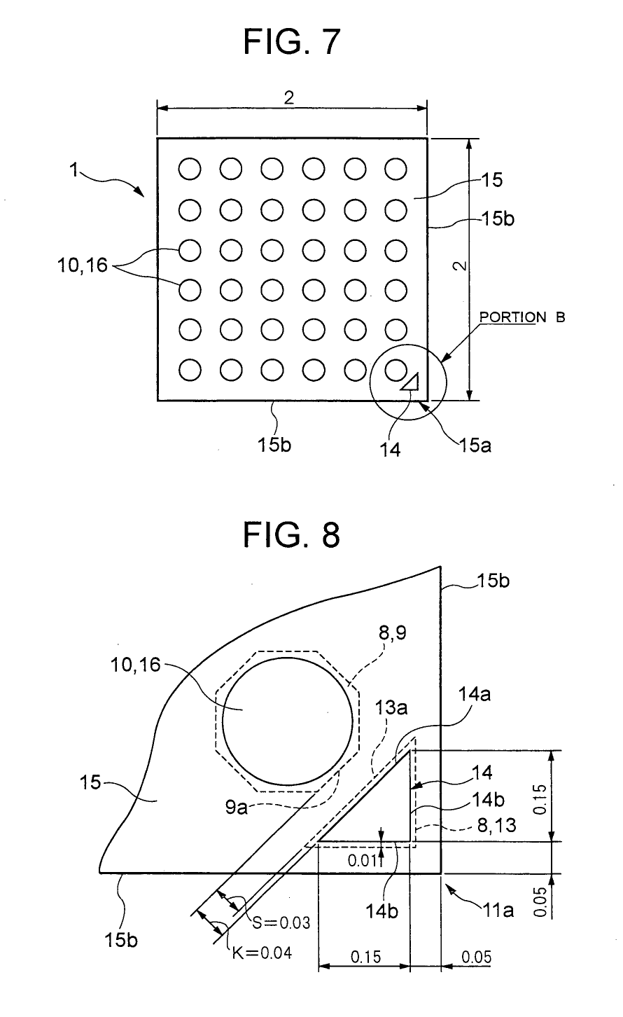

In particular, this fact is very useful when the identification mark 14 of this embodiment is provided on a small semiconductor device 1. FIG. 7 is a top view showing an example in which the identification mark of the first embodiment is formed on a small semiconductor device and FIG. 8 is an enlarged view of the portion B in FIG. 7.

The semiconductor device 1 shown in FIG. 7 is a square. The length of the side 15b of the sealing layer 15 is 2 mm. Thirty-six posts 10 and thirty-six protruding electrodes 16 are arranged in a full matrix at a pitch 0.3 mm.

In order to facilitate identification by the image identification device, the area of the identification mark 14 must be at least 0.01125 mm².

The location (or area) of the identification protrusion 12 should meet the following installation conditions: the rewiring 9 that conducts electricity to the circuit elements does not exist directly below the identification protrusion 12, the area allows provision of the nonconductive rewiring 13 that is not electrically connected to the circuit elements, the gap S between the oblique side 13a of the nonconductive rewiring 13 and the nearest side 9a of the rewiring 9 to which the neighboring post 10 is connected (see FIG. 8) is be 0.03 mm or more. The gap S is the minimum clearance to insure sufficient flow of the sealing resin. The identification protrusion 12 is provided on the nonconductive rewiring 13. The distance between the sides of the identification protrusion 12 and the corresponding sides of the nonconductive rewiring 13 must be equal to or more than 0.01 mm if the accuracy of the etching and the formation of the resist mask are considered. The distance between the side 14b of the identification mark 14 and the corresponding side 15b of the sealing layer 15 must be equal to or more than 0.02 mm if the cutting accuracy when the semiconductor wafer 20 is divided into individual pieces is considered.

When the identification mark 14 is formed in the corner 15a of the sealing layer 15 of the semiconductor device 1 shown in FIG. 7 under the above described installation conditions of the identification mark 14 and the identification protrusion 12, and the predetermined interval K between the rewiring side 9a and adjoining side 14a is set at a minimum value of 0.04 (=0.03+0.01) mm and the distance between the identification mark sides 14b and the sealing layer sides 15b is set at 0.05 mm as shown in FIG. 8, then a right-angled isosceles triangle in which the length of sides 14b is 0.15 mm and the area is 0.01125 mm² can be established as the shape of the identification mark 14.

The semiconductor devices 1 are very small and have a relatively large number of protruding electrodes arranged in a full matrix, but the shape of the identification mark is formed to be the triangle under the above described installation conditions so that the identification mark provided in the corner can have a larger area as compared to when the shape of the identification is other than the triangle such as a square or circle. Thus, identification of the identification mark provided on a small semiconductor device is easy.

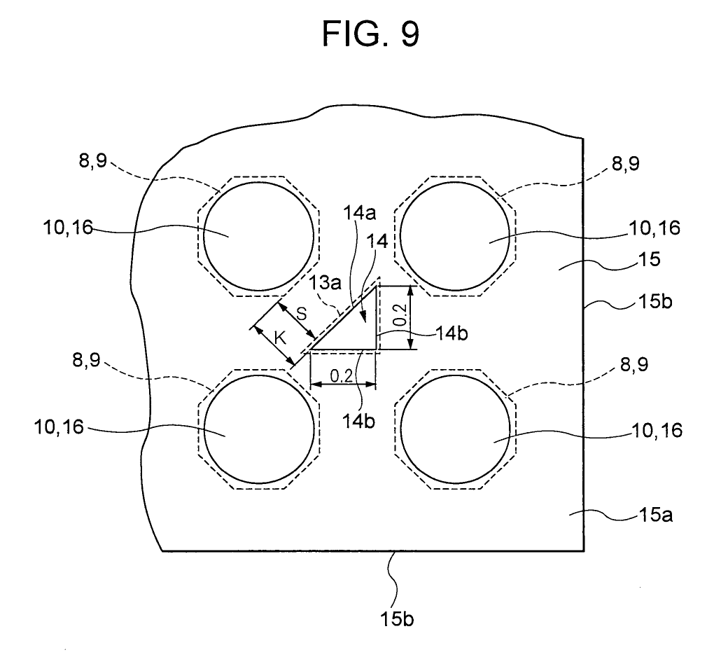

Although the identification mark 14 is formed in one corner 15a of the upper face of the sealing layer 15 in this embodiment, the location of the identification mark 14 is not limited to the corner 15a. The identification mark 14 may be provided anywhere as long as the location satisfies the above installation conditions. FIG. 9 illustrates one example. This modification will be described below.

The semiconductor device 1 shown in FIG. 9 is a square, one side of which is 2 mm. On the semiconductor device 1, sixteen posts 10 and sixteen protruding electrodes 16 are arranged in a full matrix with a pitch of 0.5 mm. Although the semiconductor device 1 is small, the protruding electrodes 16 are arranged in a full matrix with a relatively large pitch.

The right-angled isosceles triangle of the identification protrusion 14 has an oblique side 14a and two sides 14b. The oblique side 14a is formed at the predetermined interval K from one rewiring side 9a of the octagon of the rewiring 9 to which the neighboring post 10 is connected. The two sides 14b extend in parallel to the two sealing layer sides 15b respectively that form the corner 15a of the sealing layer 15. If the triangle of the identification protrusion 14 satisfies the above installation conditions, the length of the side 14b of an exemplary right-angled isosceles triangle 14 is 0.2 mm and the area is 0.02 mm².

Thus, the identification mark 14 need not always be provided in the corner of the sealing layer 15. As long as the identification mark 14 is provided other than a center area of the semiconductor device 1 (i.e., other than the area of the intersection between diagonal lines that join the corners of the square upper face of the sealing layer 15), the identification mark 14 may be provided anywhere because the direction of the semiconductor device 1 can be identified by specifying, by means of the identification mark, a quadrant that is obtained by dividing the square semiconductor device 1 into four by two orthogonal lines that extend through the center of the semiconductor device and that are parallel to the sealing layer sides 15b. Therefore, the same effect as that described above can be obtained by providing the identification mark anywhere except for the center of the semiconductor device 1.

It should be noted that the identification mark 14 can be provided at the center of the semiconductor device 1 if the identification mark 14 has a particular shape (referred to as a ‘directional shape’) which can show (tell) a certain direction by the overall shape of the identification mark or by an acute angle of the shape. This shape is, for example, a triangle except equilateral triangles, such as the right-angled triangle or the right-angled isosceles triangle. Alternatively, this shape is, for example, a trapezoid excluding isosceles trapezoids, or a home base-like shape. That is, if a directional shape is the shape of the identification mark, the identification mark can be provided anywhere on the upper face of the sealing layer 15 as long as the installation conditions are met.

### Second Embodiment

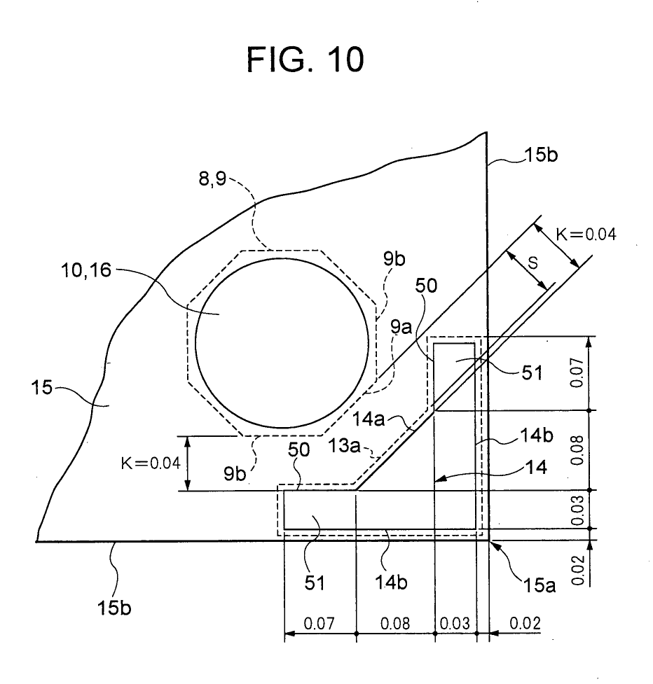

Referring to FIG. 10, a second embodiment of the present invention will be described. FIG. 10 is an enlarged view of a corner of the semiconductor device of the second embodiment.

The same symbols have been assigned to parts that are the same as those of the first embodiment and an explanation of such parts is omitted here.

The semiconductor device 1 shown in FIG. 10 is a square, and the length of one side of this square is 2 mm. Twenty-five posts 10 and twenty-five protruding electrodes 16 are arranged in a full matrix at a pitch of 0.4 mm. The semiconductor device 1 is small and the area of the corner 15a is relatively small.

In this embodiment, the identification mark 14 is constituted by an oblique side 14a, two sides 14b and two L-segments 50. The oblique side 14a is formed at the predetermined interval K from one side 9a of the octagon of the rewiring 9 to which the adjoining post 10 is connected. The two sides 14b extend in parallel to the two sealing layer sides 15b respectively that form the corner 15a of the sealing layer 15. The two L-segments 50 connect the two sides 14b to the oblique side 14a. Each L-segment 50 has two sides. One side (longer side) extends from the oblique side 14a in parallel to the side 14b and spaced at the predetermined interval K from another rewiring side 9b that lies next to the rewiring side 9a of the rewiring 9. The other side extends from the longer side to the side 14b perpendicularly. It can be said that the identification mark 14 is a triangle with two extensions 51 defined by the two L-segments 50.

It should be noted that the extension 51 may have a trapezoid shape. In this case, the segment 50 will be a J-segment.

When the identification mark 14, which is a triangle with the two extension portions 51, is formed in the corner 15a of the sealing layer 15 of the semiconductor device 1 under the above installation conditions, the identification mark 14 can have the following dimensions: the area is 0.0131 mm², the predetermined interval K is a minimum value of 0.04 mm, the distance between the identification mark side 14b and the sealing layer side 15b is a minimum value of 0.02 mm, the length of the side 14b is 0.18 mm, and the distance between the side 14b and the longer side of the L-segment 50 (width of the extension portion 51) is 0.03 mm as shown in FIG. 10.

By making the identification mark a triangle with extension portions, the area of the identification mark can be easily increased even when the identification mark should be provided in a narrow location. Thus, the identification of the mark 14 by an image identification device is easy, and the same advantages as the first embodiment can be obtained.

Although each corner (or angle) of the identification mark is constituted by straight lines in the above described embodiments, the corner may be rounded as long as the shape (e.g., triangle) of the identification mark can be identified.

It should be noted that pin marks may be provided on the lower face of the semiconductor devices, i.e., the face opposite the circuit formation face of the semiconductor substrate, by means of a stamper or a laser before or after dividing the semiconductor wafer into individual pieces in the process PA4 (FIG. 5D). If the identification mark is provided on the upper face of the semiconductor device and the pin mark is provided on the lower face of the semiconductor device, the direction of the semiconductor device can be identified easily regardless of which face is facing upward when the semiconductor device is stored in the tape & reel packaging or the tray.

This application is based on a Japanese Patent Application No. 2004-378564 filed on Dec. 28, 2004, and the entire disclosure thereof is incorporated herein by reference.

What is claimed is:

1. A semiconductor device comprising:
a semiconductor substrate having a circuit formation face;
at least one circuit element formed on the circuit formation face of the semiconductor substrate;
rewiring electrically connected to the at least one circuit element;
a plurality of posts electrically connected to the rewiring;
a column-like identification protrusion formed on the rewiring and arranged in the vicinity of one of the plurality of posts;
a sealing layer for sealing the rewiring, the column-like identification protrusion, and the posts; and
an identification mark for identifying a direction of the semiconductor device, the identification mark being made by exposing an upper end of the identification protrusion from the sealing layer.

2. The semiconductor device according to claim 1, wherein the identification protrusion is not electrically connected to the at least one circuit element.

3. The semiconductor device according to claim 1, wherein the identification mark has a directional shape.

4. The semiconductor device according to claim 3, wherein the identification mark has a first side, a second side and a third side, the first side is spaced by a predetermined distance from a lateral portion of the rewiring to which said one of the plurality of posts is connected, and the second and third sides extend in parallel to two sealing layer sides that constitute a corner of the sealing layer.

5. The semiconductor device according to claim 4, wherein the identification mark has a triangular shape, and the first side is an oblique side of the triangular shape, respectively.

6. The semiconductor device according to claim 5, wherein the triangle shape has two extension portions that extend in parallel to the two sealing layer sides.

7. The semiconductor device according to claim 1, wherein the identification mark is formed in one corner of the upper face of the sealing layer.

8. The semiconductor device according to claim 1, wherein the identification mark is formed at a center of the upper face of the sealing layer.

9. The semiconductor device according to claim 1, wherein the identification mark has a polygonal shape.

10. The semiconductor device according to claim 1 further including a second identification mark provided on a surface of the semiconductor substrate opposite the circuit formation face.

11. The semiconductor device according to claim 1, wherein a distance between said one of the plurality of posts and the identification mark is 0.03 mm or more.

12. The semiconductor device according to claim 1, wherein a distance between said second side and the sealing layer side is 0.02 mm or more.

13. The semiconductor device according to claim 1, wherein the identification mark has an area of 0.01125 mm² or more.

14. A method of fabricating a semiconductor device comprising:
providing at least one circuit element on one surface of a semiconductor substrate;
providing first rewiring that is electrically connected to the at least one circuit element;
providing second rewiring that is not electrically connected to the at least one circuit element;
providing a plurality of posts that are electrically connected to the first rewiring;
providing an identification protrusion that is connected to the second rewiring; and
providing a sealing layer that seals the first rewiring, second rewiring, posts and identification protrusion such that an end of the identification protrusion is exposed at an upper surface of the sealing layer to form an identification mark for identifying a direction of the semiconductor device.

15. The method according to claim 14, wherein the posts are provided at the same time as the identification protrusion is provided.

16. The method according to claim 14, wherein the exposed end of the identification protrusion is a polygonal.

17. The method according to claim 14, wherein the identification mark is formed in one corner of the upper face of the sealing layer.

18. The method according to claim 14, wherein the identification mark is formed at a center of the upper face of the sealing layer.

19. The method according to claim 14 further including a second identification mark provided on a surface of the semiconductor substrate opposite the one surface.

20. The method according to claim 14, wherein the identification mark has an area of 0.01125 mm² or more.
